(19) United States
(12) Patent Application Publication
(10) Pub. No.: US 2024/0345482 A1
(43) Pub. Date: Oct. 17, 2024

(54) MICRO PATTERN MANUFACTURING METHOD USING PHOTOSENSITIVE RESIN COMPOUND

(71) Applicant: CANON KABUSHIKI KAISHA, Tokyo (JP)

(72) Inventor: YOHEI HAMADE, Tokyo (JP)

(21) Appl. No.: 18/626,079

(22) Filed: Apr. 3, 2024

(30) Foreign Application Priority Data
Apr. 13, 2023 (JP) 2023-065828

(51) Int. Cl. G03F 7/039; G03F 7/004; G03F 7/029

(52) U.S. Cl. CPC G03F 7/0395; G03F 7/0045; G03F 7/029

(57) ABSTRACT

A micro pattern manufacturing method includes a first process for forming a photosensitive resin layer on a substrate, and a second process for exposing and developing the photosensitive resin layer to form a micro pattern, wherein the photosensitive resin layer is formed by using a photosensitive resin compound containing an epoxy resin, a fluorine compound, a photocationic polymerization initiator, and a solvent, and wherein a boiling or sublimation point of the fluorine compound is 200° C. or higher, the solvent contains an ester solvent, and a ratio of the ester solvent to the entire solvent is equal to or larger than 5% by mass.

### BACKGROUND

### Field

The present disclosure relates to a micro pattern manufacturing method using a photosensitive resin compound.

### Description of the Related Art

In the fields of high-tech devices such as semiconductor elements and display panels, there has been proposed a method for processing a micro pattern on a photosensitive material film by a photolithography technique to impart a functionality to the micro pattern. In particular, there has been a demand for a method for imparting a solvent resistance to a material in order to prevent pattern deformation in use in a liquid-contacting environment, and a surface treating agent for photolithography is known to impart a high water repellency and a high oil repellency to the material. As a method for more effectively imparting a solvent resistance to a material, Japanese Patent Application Laid-Open No. 10-219186 proposes a method for manufacturing a curable substance made of a cured fluorine-containing resin and a cured curable resin to improve the swelling resistance of the entire curable substance.

However, in the method discussed in Japanese Patent Application Laid-Open No. 10-219186, subjecting the resin compound to high-temperature heat processing in the curing process causes the decomposition or volatilization of a fluorine compound. In such a case, the method may not possibly exhibit desired performance. This makes it necessary to increase the addition amount of the fluorine compound in the resin compound. However, a fluorine compound having a high swelling resistance generally provides a low compatibility with organic resins such as photosensitive resins, possibly resulting in an issue of the tendency that the coating property and patterning degrade.

### SUMMARY

The present disclosure is directed to providing a method for manufacturing a micro pattern having both a high pattern accuracy and a high swelling resistance. According to an aspect of the present disclosure, a micro pattern manufacturing method includes a first process for forming a photosensitive resin layer on a substrate, and a second process for exposing and developing the photosensitive resin layer to form a micro pattern, wherein the photosensitive resin layer is formed by using a photosensitive resin compound containing an epoxy resin, a fluorine compound, a photocationic polymerization initiator, and a solvent, and wherein a boiling or sublimation point of the fluorine compound is 200° C. or higher, the solvent contains an ester solvent, and a ratio of the ester solvent to the entire solvent is equal to or larger than 5% by mass.

Further features of the present disclosure will become apparent from the following description of exemplary embodiments with reference to the attached drawings.

### BRIEF DESCRIPTION OF THE DRAWINGS

FIG. 1 is a perspective view illustrating an exemplary embodiment of a micro pattern formed by a method according to the present disclosure.

FIG. 2A is a cross-sectional view illustrating a process of applying a photosensitive resin compound onto a substrate, FIG. 2B is a cross-sectional view illustrating a process of exposing a photosensitive resin layer, and FIG. 2C is a cross-sectional view illustrating a process of removing an unexposed portion of the photosensitive resin compound.

FIG. 3A is a schematic perspective view illustrating a configuration of a liquid discharge head, and FIG. 3B is a schematic cross-sectional view illustrating the liquid discharge heard taken along the line A-B of FIG. 1A.

FIG. 4A is a schematic view illustrating a process of applying a positive type photosensitive resin onto a silicon substrate, FIG. 4B is a schematic view illustrating a process of forming a photosensitive resin layer as a discharge port material, FIG. 4C is a schematic view illustrating a process of exposing the photosensitive resin layer, FIG. 4D is a schematic view illustrating a process of developing the photosensitive resin layer, FIG. 4E is a cross-sectional view illustrating a process of forming an ink supply port, and FIG. 4F is a schematic view illustrating a process of forming an ink flow path.

### DESCRIPTION OF THE EMBODIMENTS

Exemplary embodiments of the present disclosure will be described in detail below.

The present disclosure relates to a micro pattern manufacturing method using a photosensitive resin compound containing an epoxy resin, a fluorine compound, a photocationic polymerization initiator, and a solvent. The photosensitive resin compound is characterized in that the boiling or sublimation point of the fluorine compound is 200° C. or higher, that the solvent includes an ester solvent, and that the ratio of the ester solvent to the entire solvent is 5% mass or higher. Components in the photosensitive resin compound will be described below.

### <Epoxy Resins>

An epoxy resin is used as a photosensitive resin. Although the type of the epoxy resin is not limited, an epoxy resin having a high resolution of a formed pattern, a high reactivity, and a high adhesion is preferable. More specifically, examples of suitably selectable resins include an alicyclic epoxy resin, a cresol novolac type resin, a bisphenol A type epoxy resin, a bisphenol F type epoxy resin, and a dicyclopentadiene type epoxy resin. A fluorine compound (described below) having a polar group such as a hydroxyl group can be preferably selected in order to impart a solubility. Accordingly, examples of preferably selectable epoxy resins include an alicyclic epoxy resin and a glycidyl type epoxy resin having a higher affinity with the polar group of a fluorine compound. The epoxy equivalent of the epoxy resin preferably is equal to or less than 2,000 and more preferably is equal to or less than 1,000. The epoxy equivalent equal to or less than 2,000 enables preventing the decrease in the crosslink density in the curing reaction, preventing the lowering of the glass transition temperature of a curable substance, and preventing the degradation of the adhesion. The epoxy equivalent is a value measured in conformance with JISK-7236. Specific examples of epoxy resins include a hydrogenerated bis A type epoxy resin such as a hydrogenerated bisphenol-A diglycidyl ether, and an alicyclic epoxy resin such as epoxy cyclohexane carboxylate and 1,2-epoxy-4-(2-oxiranyl) cyclohexane additive of 2,2-bis(hydroxymethyl)-1-butanol. Specific examples of commercial products of epoxy resins include the DENACOL EX-252 (Nagase ChemteX Corporation) and the EHPE-3150 (Daicel Corporation).

### <Fluorine Compounds>

Examples of selectable fluorine compounds include a fluorine compound exhibiting a sufficient swelling resistance and not volatilizing by heat during the manufacturing process, and a fluorine compound having a high compatibility with the above-described epoxy resins.

Examples of selectable low-volatility fluorine compounds include a fluorine compound having a boiling or sublimation point of 200° C. or higher. The boiling or sublimation point of a fluorine compound needs to be higher than the post-exposure heating temperature of the epoxy resin in the micro pattern forming process. To promote the curing reaction of the above-described epoxy resin, the suitable main firing temperature is 180 to 200° C. at which the curing progresses but the curable substance decomposition is restrained. Based on the above-described points, a fluorine compound having a boiling or sublimation point of 200° C. or higher is used. Examples of low-volatility fluorine compounds having a boiling or sublimation temperature of 200° C. or higher include a compound having a high molecular weight. However, because such a compound has a remarkably low solubility, an aromatic-ring-containing compound which is solid at 15 to 25° C. can be preferably selected.

From the viewpoint of the compatibility with an epoxy resin, a compound having an ether group, a hydroxyl group, or both is preferable.

Examples of aromatic ring-containing compounds having an ether group or a hydroxyl group, which is solid at normal temperature, include 2,2-bis(4-hydroxyphenyl)-hexafluoropropane, 2,2-bis [4-(4-aminophenoxy)phenyl]-hexafluoropropane, and 2,2-bis(3-amino-4-hydroxyphenyl)-hexafluoropropane. Specific examples of commercial products of fluorine compounds include the BIS-AF-A and BIS-AP-AF (Central Glass Co., Ltd.).

The amount of a fluorine compound preferably is equal to or larger than 5 parts by mass and equal to or less than 60 parts by mass and more preferably is equal to or larger than 10 parts by mass and equal to or less than 50 parts by mass with respect to 100 parts by mass of an epoxy resin. The amount of the fluorine compound equal to or less than 60 parts by mass enables restricting the amount of the non-photosensitive fluorine compound and preventing the degradation of the light patterning property. The amount equal to or larger than 5 parts by mass enables imparting a sufficient swelling resistance.

### <Solvents>

Examples of selectable solvents include a solvent of which a photosensitive resin solution is a homogeneous solution providing a uniform coating property. For this reason, an ester solvent is used as a solvent easily dissolving an organic resin and having a high affinity with the polar group of a fluorine compound. In the heating process during the coating film forming in the first process in the micro pattern manufacturing method (described below), the material agglomeration due to sudden solvent evaporation needs to be prevented. Examples of preferably usable solvents include a solvent having a boiling point higher than the heating temperature in the first process, e.g., a boiling point of 100° C. or higher. Examples of ester solvents having a boiling point of 100° C. or higher include propylene glycol monomethyl ether acetate, propylene carbonate, and isobutyl acetate. At least two different solvents can be used. To prevent the effect of an ester solvent from being degraded, it is essential that the ratio of the ester solvent in the entire solvent is equal to or larger than 5% by mass. The ratio less than 5% by mass decreases the solubility of the fluorine compound, resulting in an uneven coating film surface by the photosensitive resin solution, degrading the micro pattern formation.

From the viewpoint of the coating property, the solvent content (the total amount for two or more different solvents) preferably is equal to or larger than 30 parts by mass and equal to or less than 200 parts by mass with respect to 100 parts by mass of the epoxy resin.

### <Photocationic Polymerization Initiators>

The photocationic polymerization initiator is not limited to any specific initiator as long as the epoxy resin can be cued. To prevent the volatilization of the fluorine compound in the heating process, a low-temperature curable photocationic polymerization initiator having a high catalytic function can be preferably used. Specific examples of preferably selectable photocationic polymerization initiators include ion-based acid generating agents. Preferably selectable ion-based acid generating agents have a structure including a cationic moiety of an onium-based moiety having a high absorbability, and an anionic moiety with a borate-, phosphorus-, or antimony-based moiety having a high acid strength. Specific examples of commercial products of photoacid generating agents include the ADEKA Optomer SP-150, SP-151, SP-170, SP-171, and SP-172 (ADEKA CORPORATION).

From the viewpoint of the resin curability, the addition amount of the photocationic polymerization initiator preferably is equal to or larger than 0.5 parts by mass and equal to or less than 20 parts by mass with respect to 100 parts by mass of the epoxy resin.

### <Micro Pattern Manufacturing Methods>

The micro pattern manufacturing method according to the present disclosure includes a first process for forming a photosensitive resin layer on a substrate, and a second process for exposing and developing the photosensitive resin layer to form a micro pattern. The photosensitive resin layer is formed by using the above-described photosensitive resin compound.

Examples of the first process include the following methods:

A coating method including a coating process for applying the photosensitive resin compound according to the present disclosure onto a substrate, and a process for heating the substrate to remove a solvent to a certain extent to form a photosensitive resin layer.

A so-called dry film method for separately forming a layer of a photosensitive resin compound and then transferring the layer onto a substrate subjected to the micro pattern formation.

The micro pattern manufacturing method including the first process using the coating method will be specifically described below with reference to the accompanying drawings.

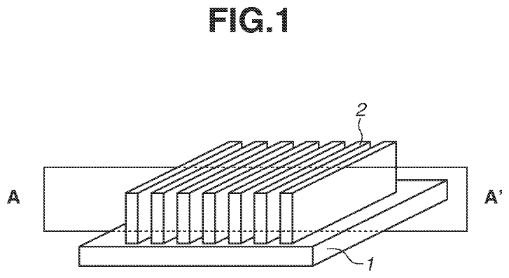

FIG. 1 illustrates an example of a micro pattern to be obtained by the method according to the present disclosure. FIG. 1 illustrates a micro pattern 2 as rectangular parallelepiped patterns disposed on a substrate 1 at predetermined intervals. However, the micro patterns 2 are not limited to the example. The present disclosure is applicable to all patterns that can be formed by using known exposure and development methods. The micro patterns 2 are formed of a curable substance of the photosensitive resin compound according to the present disclosure.

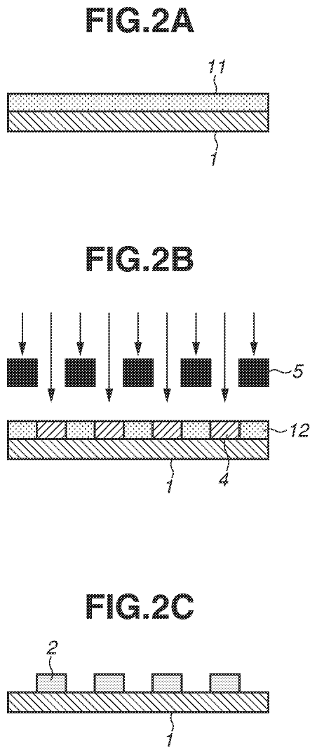

FIGS. 2A to 2C illustrate an exemplary embodiment of the micro pattern manufacturing method according to the present disclosure. FIGS. 2A to 2C are cross-sectional views illustrating processes, taken along the line A-A′ of FIG. 1. The present disclosure is not limited to the exemplary embodiment.

In the first process, the above-described photosensitive resin compound is applied to the substrate 1 as illustrated in FIG. 2A, and then the substrate 1 is heated to volatilize and remove a part of the solvent to form a photosensitive resin layer 11. The material of the substrate 1 is not particularly limited to any specific material. Examples of applicable substrates include known substrates including insulator substrates such as glass and alumina substrates, resin substrates such as plastic substrates, and metallic and semimetalic substrates such as Al and Si substrates.

The method for applying a photosensitive resin compound is not particularly limited as long as a uniform film can be formed. Examples of applicable methods include a spin coating method and a slit coating method. The heating after the coating is preferable from the viewpoint of the reactivity with the substrate 1. In this case, to prevent a non-exposed portion 12 (described below) from curing, the heating temperature is equal to or lower than the boiling point of the solvent included in the photosensitive resin compound and preferably is 70 to 120° C. The heating time is not particularly limited but can be set to, for example, 1 to 10 minutes.

In the second process, the photosensitive resin layer 11 formed in the first process is exposed. For example, as illustrated in FIG. 2B, the photosensitive resin layer 11 is exposed with a wavelength (with which a light curing reaction progresses) via a photomask 5 with a pattern formed thereon. Then, an exposed portion 4 as a latent image of a micro pattern, and a non-exposed portion 12 not exposed are formed. After the exposure process, heat processing (Post Exposure Bake (PEB)) is performed. In this case, the catalyst may spread to the non-exposed portion 12 by the post-exposure stagnation. For this reason, preferably, the PEB is performed immediately after the exposure to improve the patterning accuracy. Preferably, the temperature of the PEB is adjusted to 70° C. or higher because the reaction needs to progress so that the pattern of the exposed portion 4 is not removed in the developing process. The heat processing time is not particularly limited but may be set to, for example, 1 to 10 minutes.

More preferably, the response rate of the epoxy group of the epoxy resin is 50% or larger as a curing state of the photosensitive resin compound before this phenomenon. The response rate of the epoxy group is obtained from the ring-opening rate of the epoxy group (hereinafter referred to as the epoxy group ring-opening rate). The epoxy group ring-opening rate refers to the ring-opening percentage of the epoxy group in the epoxy resin compound. The epoxy group ring-opening rate can be calculated by using the peak area derived from the epoxy group based on the absorbance spectrum of the epoxy resin compound obtained through the Fourier transform infrared spectrometry (FT-IR). The “peak area derived from the epoxy group” refers to an integral value with respect to the base line connecting the right and left local minimal values adjacent to the peak derived from the epoxy group positioned in the vicinity of the wave number 910 cm⁻¹. More specifically, the epoxy group ring-opening rate E (%) is calculated by the following formula where X denotes the peak area in the pre-exposure absorbance spectrum and Y denotes the peak area in the post-exposure absorbance spectrum.

$$E ( \% ) = [ ( X - Y ) / X ] \times 100$$

The exposed photosensitive resin layer 11 is developed to form the micro pattern 2. For example, as illustrated in FIG. 2C, the non-exposed portion 12 of the photosensitive resin layer 11 is removed by using a solvent that can dissolve the non-exposed portion 12 to form the micro pattern 2. Preferably, the solvent (developer) used for the development is a solvent that can dissolve an uncured epoxy resin. Specific examples of usable solvents include ester solvents such as propylene glycol monomethyl ether acetate, ketone solvents such as methyl ethyl ketone and methyl isobutyl ketone, and aromatic solvents such as xylene.

A post-heating process (main firing processing after the development) is performed in order to promote the curing of the photosensitive resin compound. Preferably, the post-heating process is performed at a temperature of 140° C. or higher. In this case, preferably, the film stress of the curable substance obtained in the main firing is 20 MPa or less to prevent cracks due to the increased film stress. The film stress may be increased by thermal shrinkage and curing shrinkage. For this reason, the heating temperature in the main firing and the addition amount of the fluorine compound as an unreacting component predominantly affect this process. Accordingly, a larger addition amount of the fluorine compound enables preventing the increase in the film stress to a further extent, making it possible to perform the high-temperature main firing. For example, if the addition amount of the fluorine compound is equal to or larger than 10 parts by mass and equal to or less than 40 parts by mass with respect to 100 parts by mass of the epoxy resin, the temperature in the post-heating process in the main firing processing can be equal to or higher than 180° C. and equal to or lower than 200° C.

A method for obtaining the film stress of the curable substance will be described below.

For the measurement of the film stress, a sample having undergone not the patterning exposure but the whole surface exposure in the exposure process is prepared. Immediately after the curing of the sample, the warp variation before and after the film forming is measured by using a laser reflection type warp measuring instrument (FLX-2320-S from KLA-Tencor Corporation). The calculated internal stress is recognized as the film stress of the curable substance.

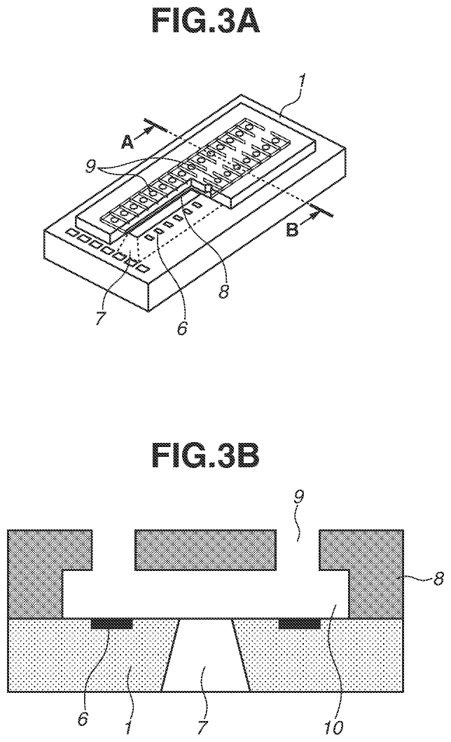

The micro pattern formed by the method according to the present disclosure has a high resolution and a high mechanical strength, and therefore is suitable for micro pattern processing in diverse fields of high-tech devices. In particular, the micro pattern can be preferably used to form the nozzle of a liquid discharge head represented by an inkjet head. For example, the photosensitive resin compound is usable as a member for forming the discharge port and the flow path of the liquid discharge head (discharge port forming member) illustrated in FIGS. 3A and 3B.

A form of a liquid discharge head, to which a micro pattern obtained by the method of the present disclosure is applied, will be described below with reference to the accompanying drawings.

FIG. 3A is a schematic perspective view illustrating the liquid discharge head according to an exemplary embodiment of the present disclosure. FIG. 3B is a schematic cross-sectional view illustrating the liquid discharge head according to an exemplary embodiment of the present disclosure, taken along a plane perpendicular to the substrate 1 passing through the line A-B in FIG. 3A.

Referring to FIGS. 3A and 3B, the liquid discharge head includes a substrate 1 on which energy generation elements 6 for producing a liquid discharge energy are formed at predetermined intervals. Examples of the energy generation elements 6 include electrothermal conversion elements and piezoelectric elements. The energy generation elements 6 may be in contact with the surface of the substrate 1 or partly separated from the surface of the substrate 1. Each of the energy generation element 6 is connected with a control signal input electrode (not illustrated) for operating the energy generation element 6. The substrate 1 is provided with an opening as a liquid supply port 7 for supplying a liquid such as ink.

Examples of the substrate 1 include a silicon substrate made of silicon. Preferably, the silicon substrate is made of a silicon monocrystal having a surface crystal orientation of (100).

A discharge port forming member 8 having discharge ports 9 is formed on the substrate 1, and the discharge port forming member 8 forms side walls of a flow path 10. According to the present exemplary embodiment, at least the discharge port forming member 8 is formed of a micro pattern formed of a curable substance of a photosensitive resin compound.

In the liquid discharge head, when a liquid such as ink supplied from the liquid supply port 7 via the flow path 10 is applied with a pressure generated by the energy generation elements 6, ink drops are discharged from the discharge ports 9 via the flow path 10.

The present disclosure will be described in detail below with reference to exemplary embodiments and comparative examples. However, the present disclosure is not limited to the configurations embodied by these exemplary embodiments. Unless otherwise specified, “part” used in the exemplary embodiments and comparative examples means “parts by mass”.

### <First to Twentieth Exemplary Embodiments and First to Twelfth Comparative Examples>

### (Manufacturing Photosensitive Resin Compounds and Manufacturing Micro Pattern Samples)

The micro pattern illustrated in FIG. 1 was manufactured in the processes illustrated in FIGS. 2A to 2C in this order.

Photosensitive resin compounds including epoxy resins, fluorine compounds, silane agents, photocationic polymerization initiators, and solvents were mixed with the compositions described in Table 1 or 2. The mixtures were stirred at normal temperature for three days, and adjusting solutions were obtained. (Samples were manufactured as described below only for solutions that were determined as homogeneous solutions.)

As illustrated in FIG. 2A, a photosensitive resin compound was applied onto a Si substrate 1 with a film thickness of 25 μm, and then subjected to the heat processing at 60° C. for nine minutes to form a photosensitive resin layer 11.

As illustrated in FIG. 2B, the photosensitive resin layer 11 was exposed to a radiant energy with a radiant quantity of 5,000 J/m2 via the photomask 5 by using an i-line exposure stepper (Canon Corporation). The pattern formation for checking the micro pattern formation was arranged so that the line/space pattern becomes 20 μm/20 μm. Subsequently, the Si substrate 1 was subjected to the heat processing at 90° C. for four minutes.

As illustrated in FIG. 2C, an unexposed portion 12 of the photosensitive resin compound was developed with a mixture of methyl isobutyl ketone (MIBK) and xylene for three minutes to be removed, and then subjected to the main firing at 200° C. to obtain a micro pattern.

### (Evaluation of Micro Pattern Samples/Evaluation Method for Film Stress)

### Swelling Resistance

The change rate of the film thickness (pattern height) before the test (after the process in FIG. 2C) and after the test (after an immersion test using a 5% water solution of 1,2-hexanediol (FUJIFILM Wako Pure Chemical Corporation) at 60° C. for three days) was obtained. The film thickness was measured by using a contactless surface measurement system (VertScan2.0 from Ryoka Systems Inc.) employing the light interference method, and then evaluated based on the following evaluation criteria.

Measurement conditions include object lens=×50, lens barrel=1.0×Body, zoom lens=NoRelay, wavelength filter=white, Measurement mode=Wave, and visual field size=640×480.
( ): The film thickness change rate before and after the test is less than 5%.
Δ: The film thickness change rate before and after the test is 5% to 10%.
x: The film thickness change rate before and after the test exceeds 10%.
Mask Reproducibility

The pattern width of the unexposed portion on the substrate was observed by using a scanning electron microscope (S-4300 from Hitachi High-Tech Corporation). The outer appearance was evaluated based on the following criteria:
( ): The line width of the line/space pattern is 20 μm, and a straight line pattern is obtained. Both the upper surface shape and the cross-sectional shape reproduce the exposure photomask.
Δ: The line width of the line/space pattern is 18 to 19 μm or 21 to 22 μm, and a straight line pattern is obtained. The upper surface shape does not slightly reproduce the photomask shape. Alternatively, a thin pattern is slightly recognized in the cross-sectional shape.
x: The line width of the line/space pattern is less than 18 μm or larger than 22 μm, and the pattern has an overhang (canopy) shape. Either the upper surface shape or the cross-sectional shape, or both do not reproduce the exposure photomask.

### Pattern Height Accuracy

The pattern height was measured by using a contactless surface measurement system (VertScan2.0 from Ryoka Systems Inc.) employing the light interference method. Measurement conditions include object lens=×50, lens barrel=1.0×Body, zoom lens=NoRelay, wavelength filter=white, measurement mode=Wave, and visual field size=640×480.

For the height accuracy, 30 points (the same points for all of the exemplary embodiments and comparative examples) in the wafer surface were measured, and 30 (standard deviation)/average value is evaluated as the distribution.
( ): 3σ/average value is less than 5% indicating that a high height accuracy is obtained.
Δ: 3σ/average value is equal to or larger than 5% and equal to or less than 10% indicating that the height accuracy slightly decreases.
x: 3σ/average value is 10% or higher indicating that the height accuracy decreases.

### Film Stress

A sample subjected to the whole surface exposure in the exposure process (and subjected to the same processing in others processes) was prepared. Immediately after the curing of the sample, the warp variation before and after the film forming was measured by using a laser reflection type warp measuring instrument (FLX-2320-S from KLA-Tencor Corporation). The calculated internal stress was recognized as the film stress of the curable substance.

### (Evaluation of Micro Pattern Samples/Evaluation Results for Film Stress)

Evaluation results are illustrated in Tables 1 and 2. The second to the sixth, the eighth to the tenth, the twelfth, the fifteenth, and the sixteenth exemplary embodiments exhibit favorable results for the swelling resistance, mask reproducibility, and pattern height accuracy. In particular, the second and the third exemplary embodiments exhibit excellent evaluation results. The first, the second, and the seventh to the eleventh comparative examples provide an inferior mask reproducibility, and the third to the seventh comparative examples provide a low swelling resistance. For the twelfth comparative example, a homogeneous adjusting solution was not obtained.

### (Manufacturing Inkjet Printing Head)

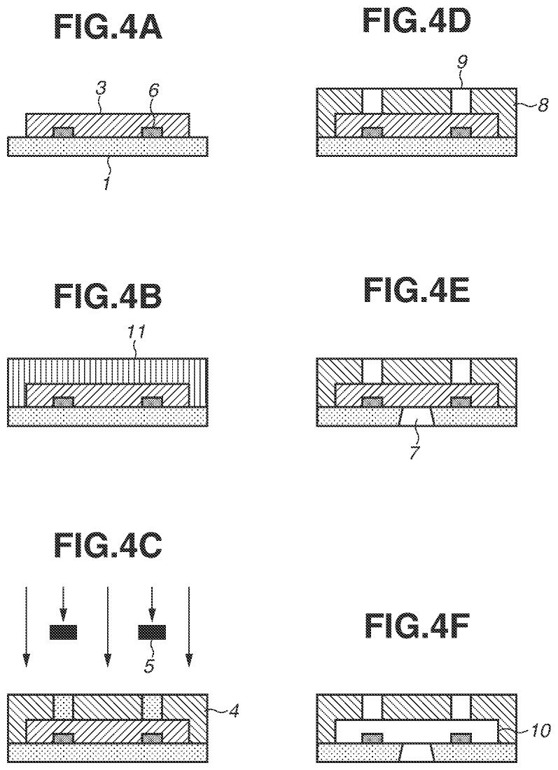

An inkjet recording head was manufactured in the processes illustrated in FIGS. 4A to 4F in this order.

As illustrated in FIG. 4A, by using the spin coating method, a positive type photosensitive resin as a mold for the ink flow path was applied onto the silicon substrate 1 with the energy generation elements 6 disposed thereon. As the positive type photosensitive resin, polymethyl isopropenyl ketone (ODUR-1010 from TOKYO OHKA KOGYO) was used. After the coating, the substrate 1 was subjected to the heat processing at 120° C. for six minutes to form a positive type photosensitive resin layer having a thickness of 14 μm. The pattern of the ink flow path was exposed by using an exposure apparatus (UX3000 from Ushio Inc.), and the exposure portion of the positive type photosensitive resin layer was developed by using methyl isobutyl ketone (MIBK). Then, the substrate 1 was subjected to rinse processing by using isopropyl alcohol (IPA) to form a mold material 3.

As illustrated in FIG. 4B, the mold material 3 and the substrate 1 were coated with the photosensitive resin compound by using the spin coating method, and then subjected to the heat processing at 60° C. for nine minutes to form the photosensitive resin layer 11 having a thickness of 25 μm as the discharge port member. According to the exemplary embodiments and the comparative examples, the photosensitive resin layer 11 is made of resin materials having the compositions to be described in the following Tables 1 and 2.

As illustrated in FIG. 4C, the substrate 1 was subjected to exposure with an exposure amount of 4,000 J/m2 via the photomask 5 by using the i-line exposure stepper and then the PEB processing at 90° C. for four minutes so that the opening finished in the upper layer of the photosensitive resin layer 11 would have a diameter of about 8.3 μm.

After the heat processing, the photosensitive resin layer 11 was subjected to development processing to form the discharge ports 9 as illustrated in FIG. 4D. After the development processing with a mixture of MIBK and xylene, the substrate 1 was subjected to rinse processing with xylene and then the main firing processing at 140° C. for four minutes.

An etching mask (not illustrated) was formed on the back surface of the substrate 1. Then, the silicon substrate 1 was subjected to anisotropic etching to form the liquid supply port 7 as illustrated in FIG. 4E. In this case, a protection film (OBC from TOKYO OHKA KOGYO) (not illustrated) was applied onto the photosensitive resin layer 11 in order to protect the discharge port forming surface from the etchant.

After dissolving and removing the protection film by using xylene, the substrate 1 was subjected to the whole surface exposure with an exposure amount of 250,000 mJ/cm2 across a negative type resist by using a deep-UV exposure apparatus (UX-3000 from Ushio Inc.) to solubilize the mold material 3. Subsequently, the substrate 1 was immersed in methyl lactate while being applied with an ultrasonic wave to dissolve and remove the mold material 3 to form the flow path 10 as illustrated in FIG. 4F. Then, the substrate 1 was subjected to the main firing processing with heat at 200° C.

The substrate 1 was subjected to implementation process including the bonding of ink supply members (not illustrated), the electrical bonding for driving the energy generation elements 6 (not illustrated), and the sealing for protecting electrical bonding portions to complete the inkjet recording head. The inkjet recording head is evaluated with the following method.

### <Evaluation Methods for Inkjet Recording Head>

Evaluation ink was injected into a tank, and then printing characteristics were evaluated with the following criteria:
(( )): Favorable with a droplet landing accuracy of 3 μm or less
( ): Within an allowable range with a droplet landing accuracy of 5 μm or less
x: With a droplet landing accuracy exceeding 5 μm

### (Evaluation Results for Inkjet Recording Head)

Evaluation results are illustrated in Tables 1 and 2. The second to the sixth, the eighth to the tenth, the twelfth, the fifteenth, and the sixteenth exemplary embodiments exhibit particularly favorable printing performance. In particular, the second and the third exemplary embodiments exhibit a further excellent printing quality. On the contrary, the first to the eleventh comparative examples provide a degraded printing quality.

TABLE 1
(1/2)

| | | Product | b.p. | Epoxy | | Exemplary embodiment | | | | |
|---|---|---|---|---|---|---|---|---|---|---|
| Item | Item | name | (° C.) | equivalent | Manufacturer | 1 | 2 | 3 | 4 | 5 |
| Photo- | Epoxy | EHPE- | — | 170-190 | Daicel | 100 | 100 | 100 | 100 | 100 |
| sensitive | resin | 3150 | | | Corporation | | | | | |
| resin | | jER157S70 | — | 200-220 | Mitsubishi | | | | | |
| compound | | | | | Chemical | | | | | |
| | | | | | Corp. | | | | | |
| | | DENACOL | — | 140 | Nagase | | | | | |
| | | EX-321L | | | ChemteX | | | | | |
| | | | | | Corporation | | | | | |
| | | jER1010 | — | 3.000-5.000 | Mitsubishi | | | | | |
| | | | | | Chemical | | | | | |
| | | | | | Corp. | | | | | |
| | Fluorine | Bis-AF | 400 | — | Central | 5 | 10 | 15 | 15 | 15 |
| | compound | | | | Glass | | | | | |
| | | Dodeca- | 205° C. | — | Tokyo | | | | | |
| | | Fluorosuberic | | | Chemical | | | | | |
| | | Acid | | | Industry | | | | | |
| | | HFAB | 99-100° C. | — | Central | | | | | |
| | | | (20 mmHg) | | Glass | | | | | |
| | | CHEMINOX | 109-110 | — | unimatec | | | | | |
| | | PO-2-ME | | | | | | | | |
| | | CHEMINOX | 155 | — | unimatec | | | | | |
| | | PO-3-ME | | | | | | | | |
| | | CHEMINOX | 187.5 | — | unimatec | | | | | |
| | | PO-2-CA | | | | | | | | |
| | | HOCH2(CF2)4CH2OH | 100° C. | — | DAIKIN | | | | | |
| | | | (3 mmHg) | | INDUSTRIES | | | | | |
| | Silane | A-187 | — | — | Momentive | 5 | 5 | 5 | 5 | 5 |
| | agent | | | | | | | | | |
| | Photocationic | SP-172 | — | — | ADEKA | 5 | 5 | 5 | 5 | 5 |
| | polymerization | CPI-410S | — | — | San-Apro | | | | | |
| | initiator | NA-CS1 | — | — | San-Apro | | | | | |
| | | NP-TM2 | — | — | San-Apro | | | | | |
| | Solvent | Xylene | 144 | — | Kishida | 95 | 95 | 95 | 90 | 80 |
| | | | | | Chemical | | | | | |
| | | Ethyl | 180.4 | — | Kishida | | | | | |
| | | Acetoacetate | | | Chemical | | | | | |
| | | Ethyl | 213.2 | — | Kishida | | | | | |
| | | Benzoate | | | Chemical | | | | | |
| | | Acetic | 156.3 | — | Kishida | | | | | |
| | | Acid 2 - | | | Chemical | | | | | |
| | | Ethoxyethyl | | | | | | | | |
| | | Propylene | 240 | — | Kishida | 5 | 5 | 5 | 10 | 20 |
| | | Carbonate | | | Chemical | | | | | |
| | | Ethyl | 77 | — | Standard | | | | | |
| | | Acetate | | | Sekiyu | | | | | |
| | | | | | Osaka | | | | | |
| | | | | | Hatsubaisho | | | | | |
| | | Ethanol | 78 | — | Kishida | | | | | |
| | | | | | Chemical | | | | | |
| | | Novec | 76 | — | Sumitomo | | | | | |
| | | 7200 | | | 3M | | | | | |
| Manufacturing | Firing condition (° C.) | | | | | 200 | 200 | 200 | 200 | 200 |
| condition | | | | | | | | | | |

| Evaluation | Solution state | * | * | * | * | * |
|---|---|---|---|---|---|---|
| | Swelling resistance | Δ | ◯ | ◯ | ◯ | ◯ |
| | Mask reproducibility | ◯ | ◯ | ◯ | ◯ | ◯ |
| | Pattern height accuracy | ◯ | ◯ | ◯ | ◯ | ◯ |
| | Film stress (Mpa) | 20 | 17 | 16 | 16 | 16 |
| | Printing characteristics | Δ | ◯ | ◯ | ◯ | ◯ |

| | | Product | b.p. | Epoxy | | Exemplary embodiment | | | | |
|---|---|---|---|---|---|---|---|---|---|---|
| Item | Item | name | (° C.) | equivalent | Manufacturer | 6 | 7 | 8 | 9 | 10 |
| Photo- | Epoxy | EHPE- | — | 170-190 | Daicel | 100 | 100 | 100 | 100 | 100 |
| sensitive | resin | 3150 | | | Corporation | | | | | |
| resin | | jER157S70 | — | 200-220 | Mitsubishi | | | | | |
| compound | | | | | Chemical | | | | | |
| | | | | | Corp. | | | | | |
| | | DENACOL | — | 140 | Nagase | | | | | |
| | | EX-321L | | | ChemteX | | | | | |
| | | | | | Corporation | | | | | |
| | | jER1010 | — | 3.000-5.000 | Mitsubishi | | | | | |
| | | | | | Chemical | | | | | |
| | | | | | Corp. | | | | | |
| | Fluorine | Bis-AF | 400 | — | Central | 40 | 60 | 15 | 15 | 15 |
| | compound | | | | Glass | | | | | |
| | | Dodeca- | 205° C. | — | Tokyo | | | | | |
| | | Fluorosuberic | | | Chemical | | | | | |
| | | Acid | | | Industry | | | | | |
| | | HFAB | 99-100° C. | — | Central | | | | | |
| | | | (20 mmHg) | | Glass | | | | | |
| | | CHEMINOX | 109-110 | — | unimatec | | | | | |
| | | PO-2-ME | | | | | | | | |
| | | CHEMINOX | 155 | — | unimatec | | | | | |
| | | PO-3-ME | | | | | | | | |
| | | CHEMINOX | 187.5 | — | unimatec | | | | | |
| | | PO-2-CA | | | | | | | | |
| | | HOCH2(CF2)4CH2OH | 100° C. | — | DAIKIN | | | | | |
| | | | (3 mmHg) | | INDUSTRIES | | | | | |
| | Silane | A-187 | — | — | Momentive | 5 | 5 | 5 | 5 | 5 |
| | agent | | | | | | | | | |
| | Photocationic | SP-172 | — | — | ADEKA | 5 | 5 | 5 | 5 | 5 |
| | polymerization | CPI-410S | — | — | San-Apro | | | | | |
| | initiator | NA-CS1 | — | — | San-Apro | | | | | |
| | | NP-TM2 | — | — | San-Apro | | | | | |
| | Solvent | Xylene | 144 | — | Kishida | 95 | 95 | 95 | 95 | 95 |
| | | | | | Chemical | | | | | |
| | | Ethyl | 180.4 | — | Kishida | | | 5 | | |
| | | Acetoacetate | | | Chemical | | | | | |
| | | Ethyl | 213.2 | — | Kishida | | | | 5 | |
| | | Benzoate | | | Chemical | | | | | |
| | | Acetic | 156.3 | — | Kishida | | | | | 5 |
| | | Acid 2 - | | | Chemical | | | | | |
| | | Ethoxyethyl | | | | | | | | |
| | | Propylene | 240 | — | Kishida | 5 | 5 | | | |
| | | Carbonate | | | Chemical | | | | | |
| | | Ethyl | 77 | — | Standard | | | | | |
| | | Acetate | | | Sekiyu | | | | | |
| | | | | | Osaka | | | | | |
| | | | | | Hatsubaisho | | | | | |
| | | Ethanol | 78 | — | Kishida | | | | | |
| | | | | | Chemical | | | | | |
| | | Novec | 76 | — | Sumitomo | | | | | |
| | | 7200 | | | 3M | | | | | |
| Manufacturing | Firing condition (° C.) | | | | | 200 | 200 | 200 | 200 | 200 |
| condition | | | | | | | | | | |

| | | | | | | |
|---|---|---|---|---|---|---|
| Evaluation | Solution state | * | * | * | * | * |

| | | | | | |
|---|---|---|---|---|---|
| Swelling resistance | ◯ | ◯ | ◯ | ◯ | ◯ |
| Mask reproducibility | ◯ | ◯ | ◯ | ◯ | ◯ |
| Pattern height accuracy | ◯ | Δ | ◯ | ◯ | ◯ |
| Film stress (Mpa) | 14 | 13 | 16 | 16 | 16 |
| Printing characteristics | ◯ | Δ | ◯ | ◯ | ◯ |

* Dissolution

TABLE 1
(2/2)

| | | Product | b.p. | Epoxy | | Exemplary embodiment | | | | |
|---|---|---|---|---|---|---|---|---|---|---|
| Item | Item | name | (° C.) | equivalent | Manufacturer | 11 | 12 | 13 | 14 | 15 |
| Photo- | Epoxy | EHPE- | — | 170-190 | Daicel | 100 | 100 | | 100 | 80 |
| sensitive | resin | 3150 | | | Corporation | | | | | |
| resin | | jER157S70 | — | 200-220 | Mitsubishi | | | 100 | | |
| compound | | | | | Chemical | | | | | |
| | | | | | Corp. | | | | | |
| | | DENACOL | — | 140 | Nagase | | | | | 20 |
| | | EX-321L | | | ChemteX | | | | | |
| | | | | | Corporation | | | | | |
| | | jER1010 | — | 3.000-5.000 | Mitsubishi | | | | | |
| | | | | | Chemical | | | | | |
| | | | | | Corp. | | | | | |
| | Fluorine | Bis-AF | 400 | — | Central | 15 | | 15 | 15 | 15 |
| | compound | | | | Glass | | | | | |
| | | Dodeca- | 205° C. | — | Tokyo | | 15 | | | |
| | | Fluorosuberic | | | Chemical | | | | | |
| | | Acid | | | Industry | | | | | |
| | | HFAB | 99-100° C. | — | Central | | | | | |
| | | | (20 mmHg) | | Glass | | | | | |
| | | CHEMINOX | 109-110 | — | unimatec | | | | | |
| | | PO-2-ME | | | | | | | | |
| | | CHEMINOX | 155 | — | unimatec | | | | | |
| | | PO-3-ME | | | | | | | | |
| | | CHEMINOX | 187.5 | — | unimatec | | | | | |
| | | PO-2-CA | | | | | | | | |
| | | HOCH2(CF2)4CH2OH | 100° C. | — | DAIKIN | | | | | |
| | | | (3 mmHg) | | INDUSTRIES | | | | | |
| | Silane | A-187 | — | — | Momentive | 5 | 5 | 5 | 5 | 5 |
| | agent | | | | | | | | | |
| | Photocationic | SP-172 | — | — | ADEKA | 5 | 5 | 5 | 5 | 5 |
| | polymerization | CPI-410S | — | — | San-Apro | | | | | |
| | initiator | NA-CS1 | — | — | San-Apro | | | | | |
| | | NP-TM2 | — | — | San-Apro | | | | | |
| | Solvent | Xylene | 144 | — | Kishida | 95 | 95 | 95 | 20 | 95 |
| | | | | | Chemical | | | | | |
| | | Ethyl | 180.4 | — | Kishida | | | | | |
| | | Acetoacetate | | | Chemical | | | | | |
| | | Ethyl | 213.2 | — | Kishida | | | | | |
| | | Benzoate | | | Chemical | | | | | |
| | | Acetic | 156.3 | — | Kishida | | | | | |
| | | Acid 2 - | | | Chemical | | | | | |
| | | Ethoxyethyl | | | | | | | | |
| | | Propylene | 240 | — | Kishida | | 5 | 5 | 5 | 5 |
| | | Carbonate | | | Chemical | | | | | |
| | | Ethyl | 77 | — | Standard | 5 | | | | |
| | | Acetate | | | Sekiyu | | | | | |
| | | | | | Osaka | | | | | |
| | | | | | Hatsubaisho | | | | | |
| | | Ethanol | 78 | — | Kishida | | | | | |
| | | | | | Chemical | | | | | |
| | | Novec | 76 | — | Sumitomo | | | | | |
| | | 7200 | | | 3M | | | | | |
| Manufacturing | Firing condition (° C.) | | | | | 200 | 200 | 200 | 200 | 200 |
| condition | | | | | | | | | | |

| Evaluation | Solution state | * | * | * | * | * |
|---|---|---|---|---|---|---|
| | Swelling resistance | ◯ | ◯ | ◯ | ◯ | ◯ |
| | Mask reproducibility | ◯ | ◯ | Δ | Δ | ◯ |
| | Pattern height accuracy | Δ | ◯ | Δ | Δ | ◯ |
| | Film stress (Mpa) | 16 | 16 | 16 | 16 | 16 |
| | Printing characteristics | Δ | ◯ | Δ | Δ | ◯ |

| | | Product | b.p. | Epoxy | | Exemplary embodiment | | | | |
|---|---|---|---|---|---|---|---|---|---|---|
| Item | Item | name | (° C.) | equivalent | Manufacturer | 16 | 17 | 18 | 19 | 20 |
| Photo- | Epoxy | EHPE- | — | 170-190 | Daicel | 100 | 100 | 100 | 100 | |
| sensitive | resin | 3150 | | | Corporation | | | | | |
| resin | | jER157S70 | — | 200-220 | Mitsubishi | | | | | |
| compound | | | | | Chemical | | | | | |
| | | | | | Corp. | | | | | |
| | | DENACOL | — | 140 | Nagase | | | | | |
| | | EX-321L | | | ChemteX | | | | | |
| | | | | | Corporation | | | | | |
| | | jER1010 | — | 3.000-5.000 | Mitsubishi | | | | | 100 |
| | | | | | Chemical | | | | | |
| | | | | | Corp. | | | | | |
| | Fluorine | Bis-AF | 400 | — | Central | 15 | 15 | 15 | 15 | 15 |
| | compound | | | | Glass | | | | | |
| | | Dodeca- | 205° C. | — | Tokyo | | | | | |
| | | Fluorosuberic | | | Chemical | | | | | |
| | | Acid | | | Industry | | | | | |
| | | HFAB | 99-100° C. | — | Central | | | | | |
| | | | (20 mmHg) | | Glass | | | | | |
| | | CHEMINOX | 109-110 | — | unimatec | | | | | |
| | | PO-2-ME | | | | | | | | |
| | | CHEMINOX | 155 | — | unimatec | | | | | |
| | | PO-3-ME | | | | | | | | |
| | | CHEMINOX | 187.5 | — | unimatec | | | | | |
| | | PO-2-CA | | | | | | | | |
| | | HOCH2(CF2)4CH2OH | 100° C. | — | DAIKIN | | | | | |
| | | | (3 mmHg) | | INDUSTRIES | | | | | |
| | Silane | A-187 | — | — | Momentive | 5 | 5 | 5 | 5 | 5 |
| | agent | | | | | | | | | |
| | Photocationic | SP-172 | — | — | ADEKA | | | | 5 | 5 |
| | polymerization | CPI-410S | — | — | San-Apro | 5 | | | | |
| | initiator | NA-CS1 | — | — | San-Apro | | 5 | | | |
| | | NP-TM2 | — | — | San-Apro | | | 5 | | |
| | Solvent | Xylene | 144 | — | Kishida | 95 | 95 | 95 | 95 | 95 |
| | | | | | Chemical | | | | | |
| | | Ethyl | 180.4 | — | Kishida | | | | | |
| | | Acetoacetate | | | Chemical | | | | | |
| | | Ethyl | 213.2 | — | Kishida | | | | | |
| | | Benzoate | | | Chemical | | | | | |
| | | Acetic | 156.3 | — | Kishida | | | | | |
| | | Acid 2 - | | | Chemical | | | | | |
| | | Ethoxyethyl | | | | | | | | |
| | | Propylene | 240 | — | Kishida | 5 | 5 | 5 | 5 | 5 |
| | | Carbonate | | | Chemical | | | | | |
| | | Ethyl | 77 | — | Standard | | | | | |
| | | Acetate | | | Sekiyu | | | | | |
| | | | | | Osaka | | | | | |
| | | | | | Hatsubaisho | | | | | |
| | | Ethanol | 78 | — | Kishida | | | | | |
| | | | | | Chemical | | | | | |
| | | Novec | 76 | — | Sumitomo | | | | | |
| | | 7200 | | | 3M | | | | | |
| Manufacturing | Firing condition (° C.) | | | | | 200 | 200 | 200 | 140 | 200 |
| condition | | | | | | | | | | |

| | | | | | | |
|---|---|---|---|---|---|---|
| Evaluation | Solution state | * | * | * | * | * |

| | | | | | |
|---|---|---|---|---|---|
| Swelling resistance | ◯ | ◯ | ◯ | Δ | Δ |
| Mask reproducibility | ◯ | Δ | Δ | ◯ | ◯ |
| Pattern height accuracy | ◯ | ◯ | ◯ | ◯ | ◯ |
| Film stress (Mpa) | 16 | 16 | 16 | 14 | 18 |
| Printing characteristics | ◯ | Δ | Δ | Δ | Δ |

* Dissolution

TABLE 2
(1/2)

| | | Product | b.p. | Epoxy | | Exemplary embodiment | | | | | |
|---|---|---|---|---|---|---|---|---|---|---|---|
| Item | Item | name | (° C.) | equivalent | Manufacturer | 1 | 2 | 3 | 4 | 5 | 6 |
| Photo- | Epoxy | EHPE- | — | 170-190 | Daicel | 100 | 100 | 100 | 100 | 100 | 100 |
| sensitive | resin | 3150 | | | Corporation | | | | | | |
| resin | | jER157S70 | — | 200-220 | Mitsubishi | | | | | | |
| compound | | | | | Chemical | | | | | | |
| | | | | | Corp. | | | | | | |
| | | DENACOL | — | 140 | Nagase | | | | | | |
| | | EX-321L | | | ChemteX | | | | | | |
| | | | | | Corporation | | | | | | |
| | | jER1010 | — | 3.000-5.000 | Mitsubishi | | | | | | |
| | | | | | Chemical | | | | | | |
| | | | | | Corp. | | | | | | |
| | Fluorine | Bis-AF | 400 | — | Central | 15 | 15 | | | | |
| | compound | | | | Glass | | | | | | |
| | | Dodeca- | 205° C. | — | Tokyo | | | | | | |
| | | Fluorosuberic | | | Chemical | | | | | | |
| | | Acid | | | Industry | | | | | | |
| | | HFAB | 99-100° C. | — | Central | | | | | | |
| | | | (20 mmHg) | | Glass | | | | | | |
| | | CHEMINOX | 109-110 | — | unimatec | | | 15 | | | |
| | | PO-2-ME | | | | | | | | | |
| | | CHEMINOX | 155 | — | unimatec | | | | 15 | | |
| | | PO-3-ME | | | | | | | | | |
| | | CHEMINOX | 187.5 | — | unimatec | | | | | 15 | |
| | | PO-2-CA | | | | | | | | | |
| | | HOCH2(CF2)4CH2OH | 100° C. | — | DAIKIN | | | | | | 15 |
| | | | (3 mmHg) | | INDUSTRIES | | | | | | |
| | Silane | A-187 | — | — | Momentive | 5 | 5 | 5 | 5 | 5 | 5 |
| | agent | | | | | | | | | | |
| | Photocationic | SP-172 | — | — | ADEKA | 5 | 5 | 5 | 5 | 5 | 5 |
| | polymerization | CPI-410S | — | — | San-Apro | | | | | | |
| | initiator | NA-CS1 | — | — | San-Apro | | | | | | |
| | | NP-TM2 | — | — | San-Apro | | | | | | |
| | Solvent | Xylene | 144 | — | Kishida | 99 | 97 | 95 | 95 | 95 | 95 |
| | | | | | Chemical | | | | | | |
| | | Ethyl | 180.4 | — | Kishida | | | | | | |
| | | Acetoacetate | | | Chemical | | | | | | |
| | | Ethyl | 213.2 | — | Kishida | | | | | | |
| | | Benzoate | | | Chemical | | | | | | |
| | | Acetic | 156.3 | — | Kishida | | | | | | |
| | | Acid 2 - | | | Chemical | | | | | | |
| | | Ethoxyethyl | | | | | | | | | |
| | | Propylene | 240 | — | Kishida | 1 | 3 | 5 | 5 | 5 | 5 |
| | | Carbonate | | | Chemical | | | | | | |
| | | Ethyl | 77 | — | Standard | | | | | | |
| | | Acetate | | | Sekiyu | | | | | | |
| | | | | | Osaka | | | | | | |
| | | | | | Hatsubaisho | | | | | | |
| | | Ethanol | 78 | — | Kishida | | | | | | |
| | | | | | Chemical | | | | | | |
| | | Novec | 76 | — | Sumitomo | | | | | | |
| | | 7200 | | | 3M | | | | | | |
| Manufacturing | Firing condition (° C.) | | | | | 200 | 200 | 200 | 200 | 200 | 200 |
| condition | | | | | | | | | | | |

| Evaluation | Solution state | * | * | * | * | * | * |
|---|---|---|---|---|---|---|---|
| | Swelling resistance | ◯ | ◯ | x | x | x | x |
| | Mask reproducibility | x | x | Δ | Δ | Δ | Δ |
| | Pattern height accuracy | x | x | ◯ | ◯ | ◯ | ◯ |
| | Film stress (Mpa) | 20 | 20 | 22 | 20 | 20 | 22 |
| | Printing characteristics | x | x | Δ | Δ | Δ | Δ |

* Dissolution

TABLE 2
(2/2)

| | | Product | b.p. | Epoxy | | Exemplary embodiment | | | | | |
|---|---|---|---|---|---|---|---|---|---|---|---|
| Item | Item | name | (° C.) | equivalent | Manufacturer | 7 | 8 | 9 | 10 | 11 | 12 |
| Photo- | Epoxy | EHPE- | — | 170-190 | Daicel | 100 | 100 | 100 | 100 | 100 | 100 |
| sensitive | resin | 3150 | | | Corporation | | | | | | |
| resin | | jER157S70 | — | 200-220 | Mitsubishi | | | | | | |
| compound | | | | | Chemical | | | | | | |
| | | | | | Corp. | | | | | | |
| | | DENACOL | — | 140 | Nagase | | | | | | |
| | | EX-321L | | | ChemteX | | | | | | |
| | | | | | Corporation | | | | | | |
| | | jER1010 | — | 3.000-5.000 | Mitsubishi | | | | | | |
| | | | | | Chemical | | | | | | |
| | | | | | Corp. | | | | | | |
| | Fluorine | Bis-AF | 400 | — | Central | 1 | | | 15 | 15 | 30 |
| | compound | | | | Glass | | | | | | |
| | | Dodeca- | 205° C. | — | Tokyo | | 15 | 40 | | | |
| | | Fluorosuberic | | | Chemical | | | | | | |
| | | Acid | | | Industry | | | | | | |
| | | HFAB | 99-100° C. | — | Central | | | | | | |
| | | | (20 mmHg) | | Glass | | | | | | |
| | | CHEMINOX | 109-110 | — | unimatec | | | | | | |
| | | PO-2-ME | | | | | | | | | |
| | | CHEMINOX | 155 | — | unimatec | | | | | | |
| | | PO-3-ME | | | | | | | | | |
| | | CHEMINOX | 187.5 | — | unimatec | | | | | | |
| | | PO-2-CA | | | | | | | | | |
| | | HOCH2(CF2)4CH2OH | 100° C. | — | DAIKIN | | | | | | |
| | | | (3 mmHg) | | INDUSTRIES | | | | | | |
| | Silane | A-187 | — | — | Momentive | 5 | 5 | 5 | 5 | 5 | 5 |
| | agent | | | | | | | | | | |
| | Photocationic | SP-172 | — | — | ADEKA | 5 | 5 | 5 | 5 | 5 | 5 |
| | polymerization | CPI-410S | — | — | San-Apro | | | | | | |
| | initiator | NA-CS1 | — | — | San-Apro | | | | | | |
| | | NP-TM2 | — | — | San-Apro | | | | | | |
| | Solvent | Xylene | 144 | — | Kishida | 100 | 100 | 100 | 95 | 100 | 100 |
| | | | | | Chemical | | | | | | |
| | | Ethyl | 180.4 | — | Kishida | | | | | | |
| | | Acetoacetate | | | Chemical | | | | | | |
| | | Ethyl | 213.2 | — | Kishida | | | | | | |
| | | Benzoate | | | Chemical | | | | | | |
| | | Acetic | 156.3 | — | Kishida | | | | | | |
| | | Acid 2 - | | | Chemical | | | | | | |
| | | Ethoxyethyl | | | | | | | | | |
| | | Propylene | 240 | — | Kishida | | | | | | |
| | | Carbonate | | | Chemical | | | | | | |
| | | Ethyl | 77 | — | Standard | | | | | | |
| | | Acetate | | | Sekiyu | | | | | | |
| | | | | | Osaka | | | | | | |
| | | | | | Hatsubaisho | | | | | | |
| | | Ethanol | 78 | — | Kishida | | | | 5 | | |
| | | | | | Chemical | | | | | | |
| | | Novec | 76 | — | Sumitomo | | | | | | |
| | | 7200 | | | 3M | | | | | | |
| Manufacturing | Firing condition (° C.) | | | | | 200 | 200 | 200 | 200 | 200 | — |
| condition | | | | | | | | | | | |

| Evaluation | Solution state | * | * | * | * | * | * |
|---|---|---|---|---|---|---|---|
| | Swelling resistance | x | ◯ | ◯ | ◯ | ◯ | — |
| | Mask reproducibility | x | x | x | x | X | — |
| | Pattern height accuracy | ◯ | ◯ | ◯ | x | X | — |
| | Film stress (Mpa) | 22 | 22 | 20 | 16 | 16 | — |
| | Printing characteristics | x | x | x | x | X | — |

* Dissolution

The present disclosure makes it possible to provide a micro pattern having a high pattern accuracy and a high swelling resistance.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-065828, filed Apr. 13, 2023, which is hereby incorporated by reference herein in its entirety.

What is claimed is:

1. A micro pattern manufacturing method comprising:
a first process for forming a photosensitive resin layer on a substrate; and
a second process for exposing and developing the photosensitive resin layer to form a micro pattern,
wherein the photosensitive resin layer is formed by using a photosensitive resin compound containing an epoxy resin, a fluorine compound, a photocationic polymerization initiator, and a solvent, and
wherein a boiling or sublimation point of the fluorine compound is 200° C. or higher, the solvent contains an ester solvent, and a ratio of the ester solvent to the entire solvent is equal to or larger than 5% by mass.

2. The micro pattern manufacturing method according to claim 1, wherein the epoxy resin is an alicyclic epoxy resin or a glycidyl type epoxy resin.

3. The micro pattern manufacturing method according to claim 1, wherein the fluorine compound is an aromatic ring-containing compound which is solid at 15 to 25° C.

4. The micro pattern manufacturing method according to claim 1, wherein the fluorine compound has an ether group, a hydroxyl group, or both.

5. The micro pattern manufacturing method according to claim 1, wherein an amount of the fluorine compound is equal to or larger than 5 parts by mass and equal to or less than 60 parts by mass with respect to 100 parts by mass of the epoxy resin.

6. The micro pattern manufacturing method according to claim 1, wherein an amount of the fluorine compound is equal to or larger than 10 parts by mass and equal to or less than 50 parts by mass with respect to 100 parts by mass of the epoxy resin.

7. The micro pattern manufacturing method according to claim 1, wherein the boiling point of the ester solvent is 100° C. or higher.

8. The micro pattern manufacturing method according to claim 1, wherein a content of the entire solvent contained in the photosensitive resin compound is equal to or larger than 30 parts by mass and equal to or less than 200 parts by mass with respect to 100 parts by mass of the epoxy resin.

9. The micro pattern manufacturing method according to claim 1, wherein an epoxy equivalent of the epoxy resin is 2,000 or less.

10. The micro pattern manufacturing method according to claim 1, wherein an epoxy equivalent of the epoxy resin is 1,000 or less.

11. The micro pattern manufacturing method according to claim 1, wherein the photocationic polymerization initiator is an ion-based acid generating agent.

12. The micro pattern manufacturing method according to claim 11, wherein a cationic moiety of the ion-based acid generating agent has an onium-based structure.

13. The micro pattern manufacturing method according to claim 12, wherein an anionic moiety of the ion-based acid generating agent has a borate-based, phosphorus-based, or antimony-based structure.

14. The micro pattern manufacturing method according to claim 1,
wherein the first process includes a process for applying the photosensitive resin compound onto the substrate and a process for heating the substrate, and
wherein a heating temperature in the heating process is equal to or lower than the boiling point of the solvent.

15. The micro pattern manufacturing method according to claim 1,
wherein an amount of the fluorine compound is equal to or larger than 10 parts by mass and equal to or less than 40 parts by mass with respect to 100 parts by mass of the epoxy resin, and
wherein the second process includes a post-heating process for performing main firing processing where a heating temperature of the post-heating process is equal to or higher than 180° C. and equal to or lower than 200° C.
